(19) United States
(12) Patent Application Publication
(10) Pub. No.: US 2018/0251885 A1
(43) Pub. Date: Sep. 6, 2018

(54) Vapor-Phase Deposition of Germanium Nanostructures on Substrates Using Solid-Phase Germanium Sources

(71) Applicants: Yize Stephanie LI, Bakersfield, CA (US); John NGUYEN, Bakersfield, CA (US)

(72) Inventors: Yize Stephanie LI, Bakersfield, CA (US); John NGUYEN, Bakersfield, CA (US)

(73) Assignee: CSUB Auxiliary for Sponsored Programs Administration, Bakersfield, CA (US)

(21) Appl. No.: 15/912,383

(22) Filed: Mar. 5, 2018

Related U.S. Application Data
(60) Provisional application No. 62/467,525, filed on Mar. 6, 2017.

(51) Int. Cl. C23C 14/16; C23C 16/06

(52) U.S. Cl. CPC C23C 14/16; C23C 16/06

(57) ABSTRACT

A method of depositing germanium on one or more substrates is disclosed. The method includes placing a source of germanium and the substrate(s) in a vapor deposition system, and heating the source of germanium in the vapor deposition system at a temperature near, at or above a melting point of elemental germanium, while flowing an inert gas over the source of germanium towards the substrate(s) for a length of time sufficient to deposit the germanium onto the substrate(s). The source of germanium is in the solid phase at ambient or room temperature. The substrate(s) may be or include one or more silicon or silicon-coated substrates, gallium nitride substrates or silicon dioxide-based substrates. The method may further include cleaning the source of germanium and the substrate(s) prior to placing the source of germanium and the substrate(s) in the vapor deposition system. The source of germanium may be elemental germanium.

### CROSS-REFERENCE TO RELATED APPLICATION

This application claims the benefit of U.S. Provisional Patent Application No. 62/467,525, filed on Mar. 6, 2017, incorporated herein by reference as if fully set forth herein.

### FIELD OF THE INVENTION

The present invention generally relates to the fields of deposition of germanium on substrates. More specifically, embodiments of the present invention pertain to deposition of germanium on silicon substrates from solid-phase germanium sources.

### DISCUSSION OF THE BACKGROUND

Existing methods of making germanium (Ge) thin films or nanostructures include molecular beam epitaxy (MBE) and ultra-high vacuum chemical vapor deposition (UHVCVD) using gaseous sources. MBE is a low throughput process that requires a sophisticated and expensive instrument. UHVCVD requires costly setups, and the gaseous sources used for growth are highly toxic and flammable. Thus, neither method is particularly suitable for large-scale, high-throughput commercial applications.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

In one aspect, the present invention relates to a method of depositing germanium on one or more substrates, comprising (a) placing a source of germanium and the substrate(s) in a vapor deposition system, the source of germanium being in the solid phase at ambient or room temperature, and (b) heating the source of germanium in the vapor deposition system at a temperature near, at or above a melting point of elemental germanium while flowing an inert gas over the source of germanium towards the substrate(s) for a length of time sufficient to deposit the germanium onto the substrate(s).

In some embodiments, the source of germanium may comprise elemental germanium. The elemental germanium may have a purity of at least 99%.

In some embodiments, the substrate(s) may comprise one or more silicon or silicon-coated substrates, gallium nitride substrates or silicon dioxide-based substrates (e.g., a silica glass or quartz).

In further embodiments, the method may comprise cleaning the source of germanium and the substrate(s) prior to placing the source of germanium and the substrate(s) in the vapor deposition system. The source of the germanium and/or the substrate(s) may be cleaned with one or more organic solvents. The method may further comprise drying the source of germanium and the substrate(s) prior to placing the source of germanium and the substrate(s) in the vapor deposition system.

In various embodiments, the source of germanium may be placed (i) in a heat-resistant boat, disk or pan that does not react with the germanium source, and/or (ii) close to, adjacent to or in a center of the vapor deposition system.

In further embodiments, the vapor deposition system may comprise a heat-resistant growth tube or chamber. The method may comprise evacuating the growth tube or chamber using a pump prior to flowing the inert gas. The growth tube or chamber may be evacuated to a pressure of 10⁻¹ Torr or less. The growth tube or chamber may comprise a quartz or alumina growth tube. In some embodiments, the inert gas may comprise argon, helium, neon, nitrogen, and/or xenon. The inert gas may have a purity of at least 99%.

In some embodiments, heating the source of germanium may comprise increasing the temperature of the furnace from room temperature to near, at or above the melting point of germanium at a rate of 1 to 100° C./min. After the temperature is near, at or above the melting point of germanium, it may be maintained for a length of time of from 1 to 1000 minutes. In some embodiments, the temperature may be from 900° C. to 1200° C.

In one embodiment, the method comprises forming a structure comprising germanium nanostructures on the substrate(s). The substrate(s) may comprise a single-crystal silicon substrate.

### BRIEF DESCRIPTION OF THE DRAWINGS

FIG. 1 shows an exemplary vapor deposition system according to one or more embodiments of the present invention.

FIG. 2 is a scanning electron microscope (SEM) image of germanium nanostructures produced by an exemplary method in accordance with an embodiment of the present invention.

FIG. 3 shows an X-ray diffraction (XRD) scan of a Ge nanostructure sample grown on a Si(100) substrate in accordance with an embodiment of the present invention.

FIG. 4 is a Raman spectrum of the germanium nanostructures produced by the exemplary method in accordance with an embodiment of the present invention.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

For the sake of convenience and simplicity, the terms “connected to,” “coupled with,” “coupled to,” and “in communication with” are generally used interchangeably herein, but are generally given their art-recognized meanings. The invention, in its various aspects, will be explained in greater detail below with regard to exemplary embodiments.

The present invention creates high quality germanium (Ge) nanostructures on silicon (Si) substrates with an efficient, low-cost, and toxic-free approach. Germanium has important applications in optoelectronics due to its pseudo-direct bandgap property and compatibility with Si-based semiconductor technology.

The present invention is based on vapor deposition of thin films using solid, non-toxic sources. The deposition takes place in a low-cost, compact physical or chemical vapor deposition system. Commercially available silicon (Si) substrates (e.g., single crystal silicon wafers which may have a diameter of 1 inch [2.5 cm], 2 inches [5 cm], 3 inches [7.5 cm], 4 inches [10 cm], 6 inches [15 cm], 8 inches [20 cm], 12 inches [30 cm], etc.) can be used as the growth substrate. In addition, the silicon substrates may be diced into smaller dimensions (e.g., from 3 mm×3 mm to 25 mm×25 mm) in any of a variety of shapes, such as square, rectangular, T-shaped, L-shaped, triangular, etc. Other substrates, such as gallium nitride and quartz, are available in similar or identical shapes and sizes.

A source of germanium (Ge) that is in the solid phase at room temperature (e.g., elemental germanium, which is non-toxic) is evaporated in a quartz or alumina growth tube at a temperature that is near, at or slightly above the melting point of Ge. In one example, the temperature is 1000° C. Germanium vapor from the heated germanium source is carried by an inert gas such as ultra-high purity argon (Ar) gas to the silicon substrate, where the germanium vapor is deposited onto the silicon substrate to solidify and form germanium nanostructures. A number of samples can be grown in a batch within a few hours, which includes a temperature ramp-up time and a cool-down time, using the present technology. The as-grown Ge samples may have the same crystal orientation as the silicon substrate. For example, when Si(100) wafers are used as growth substrates, the as-grown Ge nanostructures have a (100) orientation. Ge nanostructures with different crystal orientations can be grown using the same technique when a Si wafer having a different crystal orientation is used as the growth substrate. The as-grown Ge samples may be intrinsic (e.g., undoped) or doped with n-type or p-type dopants. The Ge samples can be characterized by scanning electron microscopy (SEM), x-ray diffraction (XRD), photoluminescence (PL) and/or Raman spectroscopy.

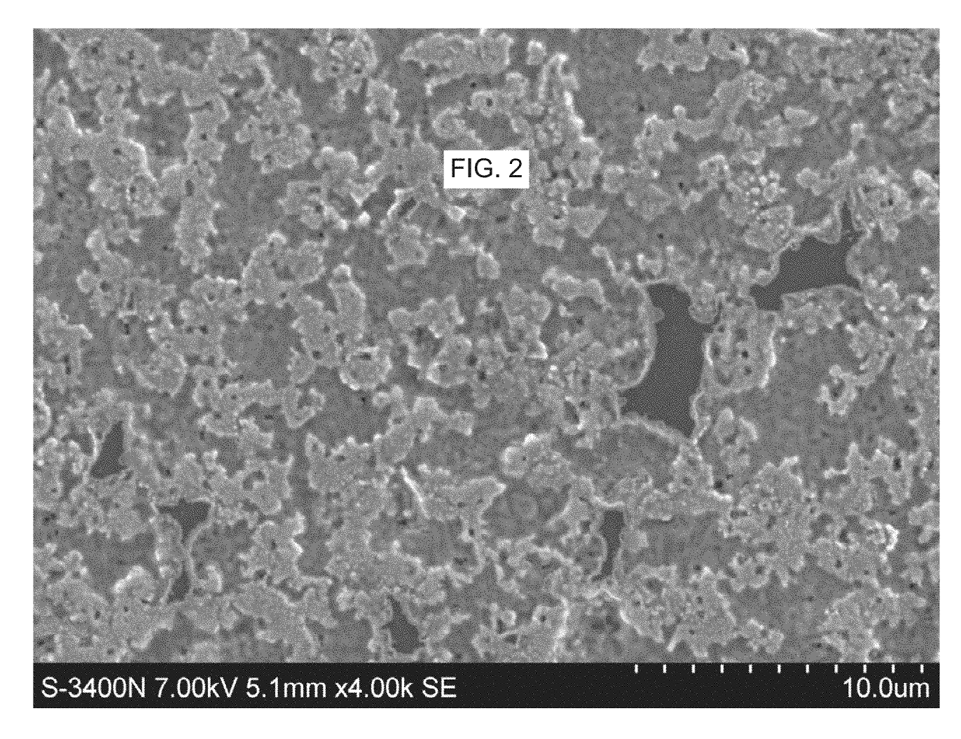

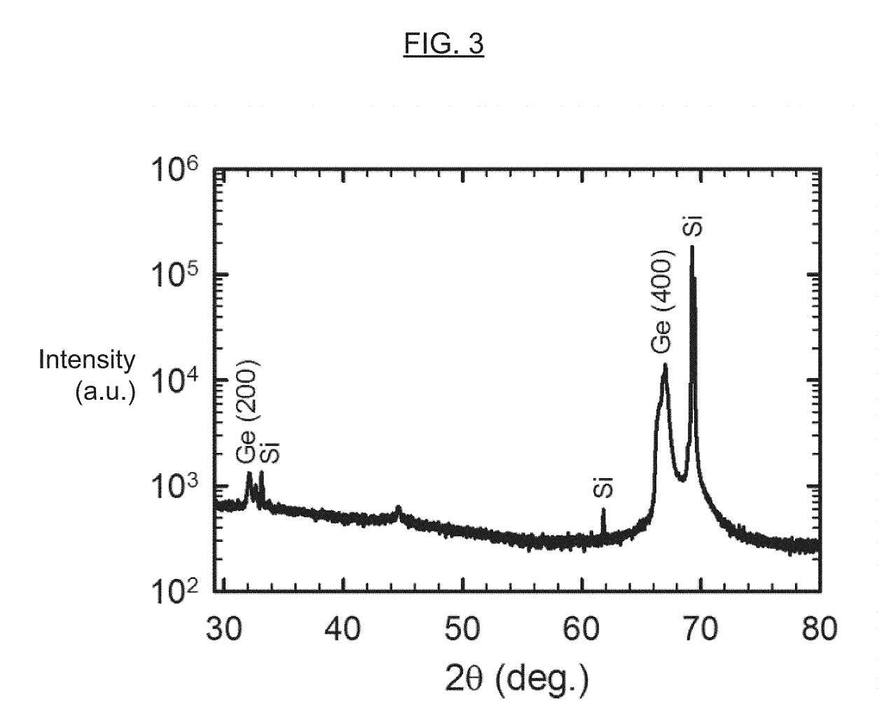

For example, the formation of nanostructures with distinct morphologies at various argon (Ar) gas flow rates are evident in SEM images of the nanostructures (e.g., FIG. 2). Moreover, the XRD 2θ-ω scan profiles indicate that germanium nanostructures made using the present method have (100) crystal orientation and better than expected crystalline quality. For example, FIG. 3 shows an XRD 2θ-ω scan of a representative Ge nanostructure sample grown on a Si(100) substrate. The peaks in the plot shown in FIG. 3 indicate the formation of Ge(100) material with high crystalline quality. Peaks resulting from the Si substrate are also labeled.

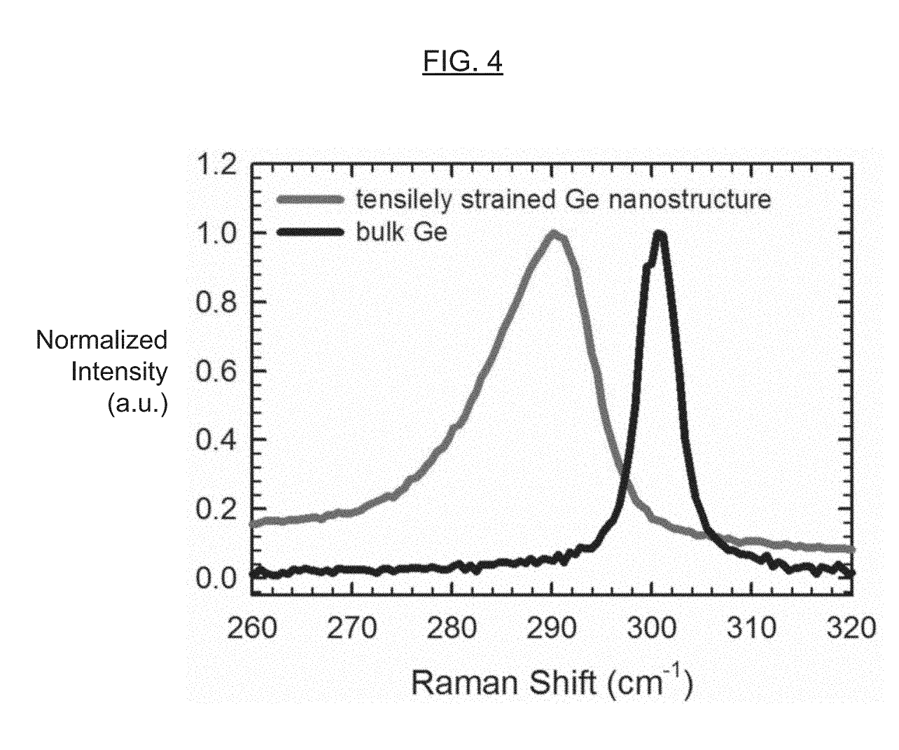

In addition, FIG. 4 shows a Raman spectrum of germanium nanostructures produced by the exemplary method below (left-hand curve), as compared to the Raman spectrum for commercial (unstrained) bulk Ge (right-hand curve). The shift of the peak location in the Raman spectrum of germanium nanostructures produced by the exemplary method below relative to that of unstrained Ge is on the order of 10-12 cm⁻¹, but the actual value may differ or vary from sample to sample. The data in FIG. 4 indicates that the Ge material (deposited on a single-crystal Si substrate) is tensilely strained. However, if the Ge is deposited on another substrate, it may be unstrained or compressively strained. The actual strain value for the sample in the left-hand curve is 2.52%.

A major advantage of the present invention (i.e., vapor deposition of germanium nanostructures using a solid germanium source) over existing methods based on MBE or UHVCVD growth is that it eliminates the need for expensive instruments, as well as toxic and/or flammable gases, and it facilitates high-throughput and/or large-scale production of high quality germanium nanostructures.

The germanium-on-silicon materials produced by the present invention are suitable for practical applications in optoelectronics. The economic potential and commercial applications for the present invention are significant, as it may (i) reduce the instrument cost by 10 to 100 times, (ii) increase the efficiency of production substantially, and (iii) eliminate the need for toxic and/or flammable gases.

### An Exemplary Method of Depositing Germanium on a Substrate Using a Solid Germanium Source

In an exemplary procedure in accordance with the present invention, germanium (e.g., a piece of elemental germanium having a purity of about 99.9999%) and one or more substrates (e.g., silicon(100) or other single-crystal silicon substrates, glass, silicon or other mechanically rigid substrates coated with single-crystal [e.g., epitaxial], polycrystalline, microcrystalline and/or amorphous silicon, gallium nitride substrates, quartz or other silicon dioxide-based [e.g., glass] substrates, etc.) are cleaned by rinsing with acetone, followed by with isopropyl alcohol. However, rinsing with one or more organic solvents (e.g., acetone, methanol, ethanol, isopropanol, diethyl ether, tetrahydrofuran, hexanes, petroleum ether, benzene, toluene, etc.) to remove any organic contaminants on the surface of the germanium source and/or the substrate(s) is suitable. Elemental germanium having a lower purity (e.g., at least 99%, at least 99.9%, etc.) is also suitable, but the nanostructure quality may not be as high. Other sources of elemental germanium (e.g., germanium nanoparticles) may also be effective. Next, the germanium and the silicon substrate(s) are dried. For example, the germanium and the silicon substrate(s) may be dried in air (e.g., in a fume hood) or in an inert gas, such as argon or nitrogen. In further embodiments, the substrate(s) may be heated to a temperature of 30 to 150° C., or any temperature or range of temperatures therein (e.g., 50 to 120° C.), during the drying process.

Subsequently, the germanium is placed in one end of a quartz boat, although any heat-resistant disk or pan that does not react with the germanium source is suitable (e.g., an alumina pan or boat). In addition, the silicon substrates are placed close to the germanium, side-by-side along the boat. The quartz boat having the germanium source therein and the silicon substrates therein are loaded in the quartz growth tube of a chemical vapor deposition (CVD) system, such that the germanium source is close to the center of the furnace of the CVD system. Other heat-resistant tubes or chambers allowing gas flow (e.g., relatively non-turbulent gas flow) through the tube or chamber are also acceptable, and other vapor-phase deposition systems (e.g., a physical vapor deposition system such as an evaporation chamber equipped with a gas inlet and a separate gas outlet) are also suitable.

The quartz growth tube is closed and evacuated using a mechanical pump, reaching a pressure of around 1×10⁻² Torr. Next, Ar gas (e.g., argon gas having a purity of at least 99.999%) is introduced into the quartz growth tube. Other inert gases, such as helium, neon, nitrogen, xenon, etc. may also be suitable, as may other purities of the inert gas (e.g., at least 99%, at least 99.9%, etc.). Pressures of from 0.5 Torr to 10 Torr (including 5 Torr, 2 Torr and 1 Torr) have been used in various embodiments, although any pressure of from about 0.05 Torr to several hundred Torr (e.g., 300 Torr) or higher (e.g., up to atmospheric pressure) may be used.

In exemplary embodiments of the present invention, the temperature of the CVD system is increased from room temperature to 1000° C. gradually (e.g., at a rate of 1-50° C./min or any value or range of values therein, such as 10° C./min). The temperature of the CVD system is then held at 1000° C. (a temperature slightly above the melting point of Ge) for 30 minutes to deposit the germanium onto silicon substrates. Other temperatures may be suitable (e.g., from 900-1200° C., or any value or range of values therein), but the deposition rate may depend on the temperature of the germanium source, the distance of the silicon substrates from the germanium source, the flow rate of the inert gas, etc.

The CVD system is cooled down naturally, and the argon flow remains until the temperature drops below 800° C. Typically, the samples may be retrieved from the quartz growth tube when the temperature is below 50° C. The samples may be characterized by optical microscopy, SEM, PL, Raman spectroscopy, and/or XRD.

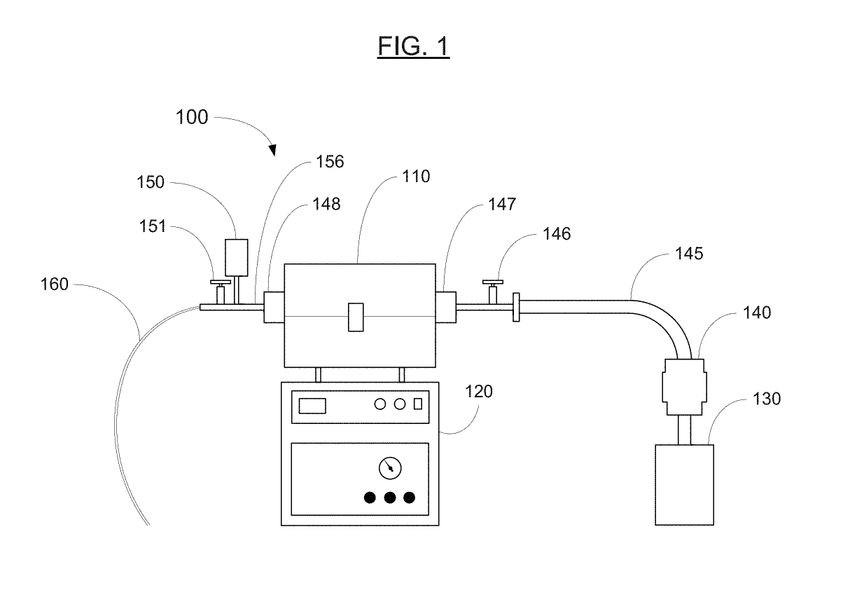

FIG. 1 is a diagram of an exemplary vapor deposition system 100 according to one or more embodiments of the present invention. The vapor deposition system includes a furnace 110 having a quartz growth tube therein (not shown), tube inlet and outlet connectors 148, 147, respectively, that extend outside the furnace 110, and a temperature controller 120. In addition, the present vapor deposition system 100 includes a pump (e.g., a mechanical pump) 130 that is connected to the tube outlet connector 147 through a valve 146.

In exemplary embodiments, a solid germanium source (e.g., elemental germanium) and the substrate(s) are placed in the quartz growth tube. The elemental germanium is generally placed in a dish or boat made of a material with a higher melting point, such as quartz. Generally, the solid germanium source is placed in close proximity or adjacent to the center of the furnace 110 or in the center of the furnace 110.

The temperature controller 120 is configured to heat the germanium source at a temperature at, near or above the melting point of germanium (938° C.). The temperature controller 120 may increase the temperature at a rate of from 1° C./min to 100° C./min, or any rate therein. The temperature may be maintained for a length of time of from 1 to 1000 minutes (or any length or range of lengths of time therein, such as 30 minutes) to form germanium nanostructures on the substrate.

The mechanical pump 130 has an oil mist filter 140 and a hose 145 connected to the tube outlet connector 147. The mechanical pump does not have to be a higher-vacuum pump. In addition, a pressure of 10⁻³ to 10⁻¹ Torr (e.g., 1×10⁻² Torr) may be maintained by the mechanical pump. Valve 146 may be used to control the pressure in the growth tube.

In addition, the present system may include a gas inlet 156 configured to introduce an inert gas from a supply line or tube 160 to the tube connector 148. In one example, the inert gas is ultra-high purity argon, but other inert gases (e.g., nitrogen, helium, neon, etc.) may be suitable. Generally, the inert gas may have a purity of at least 99% (e.g., 99.999%). The gas inlet 156 may be connected to a pressure gauge 150 and may have a valve 151 configured to control the amount or flow of inert gas introduced to the growth tube. The quartz growth tube receives the inert gas to transport germanium vapor to the substrate(s), forming the germanium nanostructures or film(s) thereon. FIG. 2 shows a Scanning Electron Microscope (SEM) image of germanium nanostructures made using an example of the present method. Germanium-on-silicon materials produced by the present invention are suitable for practical applications in optoelectronics.

### CONCLUSION

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed, and that modifications and other embodiments are intended to be included within the scope of the appended claims. Although specific terms are employed herein, they are used in a generic and descriptive sense only, and not for purposes of limitation.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A method of depositing germanium on one or more substrates, comprising:
a) placing a source of germanium and said one or more substrates in a vapor deposition system, said source of germanium being in a solid phase at ambient or room temperature; and
b) heating said source of germanium in said vapor deposition system at a temperature near, at or above a melting point of elemental germanium while flowing an inert gas over the source of germanium towards said one or more substrates for a length of time sufficient to deposit said germanium onto said one or more substrates.

2. The method of claim 1, wherein said source of germanium comprises elemental germanium.

3. The method of claim 2, wherein said elemental germanium has a purity of at least 99%.

4. The method of claim 1, wherein said one or more substrates comprise one or more silicon or silicon-coated substrates, gallium nitride substrates or silicon dioxide-based substrates.

5. The method of claim 1, further comprising cleaning said source of germanium and said one or more substrates prior to placing said source of germanium and said one or more substrates in said vapor deposition system.

6. The method of claim 5, wherein cleaning said source of germanium and said one or more substrates comprises cleaning with one or more organic solvents.

7. The method of claim 5, further comprising drying said source of germanium and said one or more substrates prior to placing said source of germanium and said one or more substrates in said vapor deposition system.

8. The method of claim 1, wherein said source of germanium is placed close to, adjacent to or in a center of the vapor deposition system.

9. The method of claim 1, wherein said source of germanium is placed in a heat-resistant boat, disk or pan that does not react with the germanium source.

10. The method of claim 1, wherein said vapor deposition system further comprises a heat-resistant growth tube or chamber.

11. The method of claim 10, further comprising evacuating said growth tube or chamber using a pump prior to flowing said inert gas.

12. The method of claim 11, wherein said growth tube or chamber is evacuated to a pressure of 10⁻¹ Torr or less.

13. The method of claim 10, wherein said growth tube or chamber comprises a quartz or alumina growth tube.

14. The method of claim 1, wherein said inert gas comprises argon, helium, neon, nitrogen, and/or xenon.

15. The method of claim 14, wherein said inert gas has a purity of at least 99%.

16. The method of claim 1, wherein heating said source of germanium comprises increasing said temperature of said furnace from room temperature to near, at or above the melting point of germanium at a rate of 1 to 100° C./min.

17. The method of claim 1, wherein said temperature near, at or above the melting point of germanium is maintained for a length of time of from 1 to 1000 minutes.

18. The method of claim 1, wherein said temperature near, at or above the melting point of germanium is from 900° C. to 1200° C.

19. A structure comprising germanium nanostructures formed on said one or more substrates by the method of claim 1.

20. The structure of claim 19, wherein each of said one or more substrates comprises a single-crystal silicon substrate.
